(19) United States
(12) Patent Application Publication
(10) Pub. No.: US 2006/0197566 A1
(43) Pub. Date: Sep. 7, 2006

(54) DLL circuit for providing an output signal with a desired phase shift

(76) Inventors: Andreas Jakobs, Munich (DE); Andreas Taeuber, Unterschleissheim (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/358,940

(22) Filed: Feb. 21, 2006

(30) Foreign Application Priority Data
Feb. 19, 2005 (DE) 102005007652.1-42

(51) Int. Cl. H03L 7/06

(52) U.S. Cl. 327/158

(57) ABSTRACT

The present invention relates to a DLL circuit for providing an output signal which is shifted with by a desired phase shift with respect to a periodic input signal. In one embodiment, the DLL Circuit comprises a plurality of delay elements all having the same delay time and being connected in series to form a delay chain, wherein the periodic input signal is applied to the first delay element of the delay chain. The DLL circuit further comprises a detection unit which is connected to the outputs of at least a portion of the delay elements and which is provided to determine which delay element a particular edge of the periodic signal has reached after a predetermined phase progress of the periodic signal, and to generate a corresponding control information which indicates at which delay element the particular edge of the periodic signal has last been determined. The DLL circuit further comprises a selection circuit for selecting one of the delay elements depending on the control information and depending on the desired phase shift and outputting the signal at the output of the selected delay elements as the output signal of the DLL circuit.

### CROSS-REFERENCE TO RELATED APPLICATIONS

This application claims foreign priority benefits under 35 U.S.C. §119 to co-pending German patent application number DE 10 2005 007 652.142, filed 19 Feb. 2005. This related patent application is herein incorporated by reference in its entirety.

### BACKGROUND OF THE INVENTION

1. Field of the Invention

The present invention relates to a DLL circuit for providing an output signal which is shifted with regard to a periodic input signal by a desired phase shift.

2. Description of the Related Art

In integrated circuits, controlled delay elements formed by delay locked loop (DLL) circuits are used to derive an output signal with a fixed phase relation from a given periodic input signal. The periodic shift between the output signal and the periodic input signal is indicated in fractions of the period time or in degrees. The phase relation is to be kept constant independently from the frequency of the periodic input signal as well as from external influences such as process parameters, operating voltage and temperature fluctuations (e.g., PVT or process/voltage/temperature) and the like. A conventional DLL circuit comprises a number of delay elements connected in series in order to form a delay chain. The delay elements exhibit identical signal delays which may be controlled via a suitable control signal. The control signal is determined from the phase difference between the periodic input signal at the input port of the delay chain and the signal at the output port of the delay chain. This control loop is designed so that, by changing the delay of the individual delay elements, the phase difference between the input signal and the signal at the output port of the delay chain always corresponds to a fixed value, e.g., 180°. To a certain extent, this can always be achieved independently from the frequency and the influence of process parameters, operating voltage and the process parameters.

At the outputs of the individual delay elements of the delay chain, signals having differing phase shifts are provided which may be tapped for processing in a subsequent circuit. To design adjustable delay elements, in particular with regard to their linearity, to their range of adjustment and to their resolution of the delay time depending on the control signal, is very complex. Also, in such a control loop, the phase detector and a potential loop filter have to meet high standards, since even with a small change of the respective control value, a multiple effect on the resolution of the phase difference between the input signal and the signal at the output of the delay chain is caused. Furthermore, the inherent delay between the changing of the control signal and the corresponding reaction at the output of the delay chain have to be considered when determining the control characteristics.

### SUMMARY OF THE INVENTION

One advantage of the present invention is to provide a DLL circuit for providing an output signal having a desired phase shift, which can be easily manufactured.

According to a first aspect of the present invention, a DLL circuit for providing an output signal is provided which is shifted by a desired phase shift with regard to a periodic input signal. The DLL circuit comprises a number of delay elements, each having the same delay time, which are connected in series to form a delay chain. The periodic input signal is applied to the first delay element of the delay chain. The DLL circuit further comprises a detection unit connected to the output ports of at least a part of the delay elements of the delay chain and provided to determine at which delay element a particular edge of the periodic signal has reached after a predetermined phase progress of the periodic signal, and to generate a corresponding control information which indicates at which delay element the particular edge of the periodic signal has last been determined. Furthermore, a selection circuit is provided for selecting one of the delay elements depending on the control information and depending on the desired phase shift, and outputting the signal at the output port of the selected delay elements as the output signal of the DLL circuit.

The DLL circuit according to the invention has the advantage that a particular phase shift may be realized in a simple manner. In particular, use is made of delay elements with a predefined delay time, so that the provision of adjustable delay elements can be dispensed with. Adjustment of the delay to the frequency of the input signals in order to set the phase shift and to compensate for the influences of process parameters, operating voltage and temperature fluctuations, is carried out by varying the delay element which is selected for outputting the output signal. Instead of determining a fixed number of adjustable delay elements, the delay chain is provided with a number of fixed delay elements, and the delay element in the delay chain at which a predefined phase progress occurs is determined. A corresponding control information is generated indicating this delay element of the delay chain, and by means of a selection circuit, an output port of one of the delay elements is selected depending on the determined control information and depending on the desired phase shift of the periodic input signal.

A further delay chain can be provided which is substantially identical in design to the delay chain and comprises an associated further selection circuit for selecting one of the delay elements in the further delay chain depending on the control information and depending on a desired further phase shift and for outputting the signal at an output of the selected delay element of the further delay chain as a further output signal. In this manner, an already determined control information can be used to carry out different phase shifts in a plurality of input signals having the same frequency. Furthermore, a phase shift of a further input signal can be realized with a differing frequency if the relation between the frequency and the periodic input signal provided to define the control information and the further periodic input signal is known. Moreover, a particular phase shift, e.g., for a non-periodic signal at the further delay chain can also be set in the case of a predefined frequency of the periodic input signal and depending on the control information.

According to a preferred embodiment, the detection unit comprises a plurality of D-flip-flop circuits, each connected to the output ports of various delay elements of the delay chain, the periodic input signal phase shifted with the predetermined phase progress being applied to the clock input ports of the D-flip-flop circuits in order to latch the signal at the output ports of the respective delay elements into the corresponding D-flip-flop circuit in accordance with the edge delayed by the predetermined phase progress. The evaluation circuit is provided in such a way that the control information is generated depending on the memory values of the D-flip-flop circuits. This represents a particularly simple realization of the detection unit.

The detection unit may preferably be provided to apply the periodic signal to the clock input port of the D-flip-flop circuits in order to provide a phase progress of 360°. Alternatively, the detection unit may be provided in order to apply the inverted periodic signal to the clock input port of the D-flip-flop circuits in order to provide a phase progress of 180°.

Practically, the D-flip-flop circuits are preferably realized in such a way that the periodic input signal charged with the predetermined phase progress is applied to the clock input ports substantially at the same time.

According to a preferred embodiment of the DLL circuit, the selection unit is operable such that the delay element from the chain of delay elements is selected at a predefined position, and the signal at the output port of the selected delay element is outputted as the output signal. The position of the delay element is determined by the desired phase shift divided by the individual phase shift of one of the delay elements, the individual phase shift being determined by the control information and the predetermined phase progress.

According to a further aspect, a DLL circuit is provided for providing an output signal which is phase-shifted with a desired phase shift with regard to a periodic input signal, the DLL Circuit comprising a plurality of delay elements each having the same delay time and being connected in series to form a delay chain, wherein the periodic input signal is applied to the first delay element of the delay chain, a detection unit which is connected to the outputs of at least one part of the delay elements and which is provided to determine at which delay element a particular edge of the periodic signal has reached after a predetermined phase progress of the periodic signal, and to generate a corresponding control information which indicates at which delay element the particular edge of the periodic signal has last been detected, and a selection circuit to select one of the delay elements depending on the control information and depending on the desired phase shift and to output as the output signal of the DLL circuit one of an inverted signal and a non-inverted signal at the output of the respective delay element which is selected depending on the desired phase shift.

According to a further aspect of the present invention, a clock frequency doubling circuit is provided with such a DLL circuit. The clock frequency doubling circuit comprises a DLL circuit, in which the selection unit is set such that the desired phase shift is 90°. The frequency doubling circuit further comprises an exclusive OR-gate linking the periodic signal and the 90° phase-shifted periodic signal in order to obtain an output signal with a doubled clock frequency at the output port of the exclusive OR-gate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a circuit diagram of a DLL circuit according to a first embodiment of the present invention;

FIG. 2 illustrates a signal-time-diagram of the individual signals of the DLL circuit of FIG. 1;

FIG. 3 shows a DLL circuit comprising two delay chains for setting a phase shift or a time delay according to a further embodiment of the present invention;

FIG. 4 shows a DLL circuit for providing an output signal, the phase shift of which may be set with regard to the input signal; and

FIG. 5 illustrates a clock frequency doubling circuit according to a further embodiment of the present invention.

### DETAILED DESCRIPTION OF THE PREFERRED EMBODIMENT

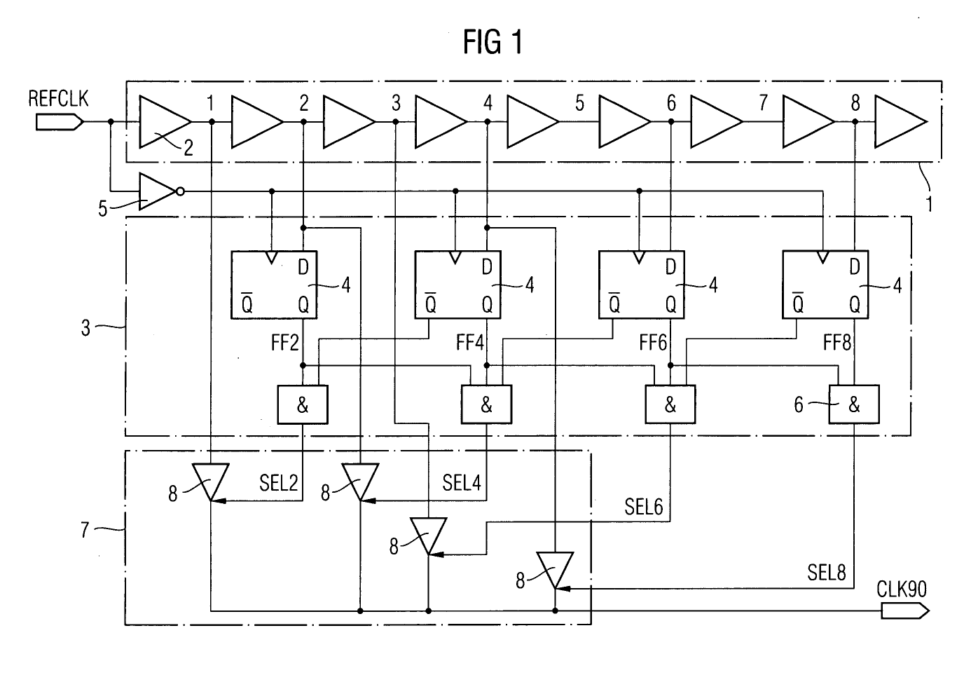

FIG. 1 shows a DLL circuit according to the first embodiment of the present invention in a block diagram. The DLL circuit comprises a delay chain 1 which (in the present embodiment) comprises serially connected delay elements 2. The delay elements 2 are preferably identical in design and thus comprise predetermined, virtually identical signal delays. The signal delay is selected such that it is significantly smaller than the periodic duration of an applied periodic input signal REFCLK. In the shown embodiment, the periodic input signal is a reference clock signal which is, e.g., applied to an integrated circuit which is making use of the DLL circuit. The delay elements 2 of the delay chain 1 may, e.g., each comprise two sequentially connected inverter circuits, permanently switched transmission gates or other typically used elements, which cause a signal delay. In an integrated design, an identical design of the delay elements substantially guarantees an identical signal delay.

Moreover, a detection unit 3 is provided comprising input ports connected to output ports of some of the delay elements 2. Which output ports of the delay elements are connected to the detection unit 3 substantially depends on the desired resolution of the detection unit 3. It can also be provided that the output ports of each delay element 2 is connected with a corresponding detection unit 3. In the present example, only the output port of every second delay element 2 is connected to the detection unit 3.

The detection unit 3 comprises a D-flip-flop 4 for each corresponding input port wherein the output port of the corresponding delay element 2 is connected to a data input port D of the associated D-flip-flops 4. The D-flip-flops 4 are identified as first to fourth D-flip-flops, starting from the D-flip-flop on the left side of FIG. 1. The D-flip-flops 4 furthermore each comprise a clock input port to which a common reference signal is applied. The reference signal is derived from the periodic input signal and comprises a clearly defined phase progress with regard to the input signal. In the present example, a phase progress of 180° is defined for a periodic input signal having a duty cycle of 1:1 by means of an inverter 5. Alternatively, it is possible to omit the inverter 5 and to apply the periodic input signal to the clock input ports of the D-flip-flops 4 in order to realize a phase progress of 360°. The application of a signal to the clock input ports of the D-flip-flops, the signal comprising a deviation phase progress with regard to the input signal, is, e.g., also conceivable in the case of a deviating duty cycle of the input signal.

Each of the D-flip-flops preferably comprises an inverting output port \overline{Q} and a non-inverting output port Q. The output ports of the D-flip-flops are connected to a corresponding number of AND gates 6 which are connected in such a way that after taking over the signals applied to the output ports of the corresponding delay elements 2, and in the case of a rising edge at the clock input port, they receive the values stored in the D-flip-flops. Only that AND-gate 6 which, in the row of D-flip-flops 4 associated with the delay elements 2, has last recognized that a signal edge of the periodic input signal has reached the corresponding delay element 2, issues a logic “1”. In the present example, the AND gates 6 essentially verify that the associated D-flip-flop stores a logic “1”, that the preceding D-flip-flop also stores a logic “1” and that the subsequent D-flip-flop stores a logic “0”, thereby indicating that the corresponding edge of the periodic input signal has not yet reached the delay element 2 associated with the subsequent D-flip-flop. Contrary thereto, the first AND gate 6 which is associated with the first D-flip-flop 4 only comprises two input ports connected to the non-inverting output port of the first D-flip-flop and the inverting output port of the second D-flip-flop 4. The fourth and last AND gate 6, which is associated with the fourth and last D-flip-flop 4, is coupled to the non-inverting output ports of the third and fourth D-flip-flop 4 by its input ports.

The output ports of the AND gates 6 correspond to selection signals and indicate, in the form of a control information, which delay element 2 in the delay chain 1 has been reached by a corresponding edge of the periodic input signal. The selection signals are indicated by SEL followed by the number of the delay element in which the corresponding edge has last been detected. For example, a logic “1” of the selection signal SEL4 means that a corresponding edge of the periodic input signal has already been recognized at the fourth delay element 2 and not yet at the sixth delay element 2. For the purpose of clarity, the example only shows the generation of the selection signal after the second, the fourth, the sixth and the eighth delay element 2 and the selection signals SEL2, SEL4, SEL6 and SEL8 generated therefrom. Since the DLL circuit shown in FIG. 1 serves to generate an output signal with a phase shift of 90° with regard to the periodic input signal, the output signals are used to apply certain outputs of the delay elements 2 to the output of the DLL circuit. For this purpose, the selection unit 7 comprises switchable output drivers 8 which may be set to a high resistive state or be turned on (or off) by means of the output signal. Since only one of the output signals SEL comprises a logic “1” while the other selection signals issue a logic “0”, only one of the output drivers is turned on, while the others are turned off.

By means of a phase progress 180° determined by the inverter 5, a desired phase shift of 90° between the output signal and the periodic input signal can be achieved by connecting the output port of the DLL circuit to the output port of that delay element 2 the position number of which within the delay chain 1 is halved with regard to the position number of the delay element, which has last detected the corresponding edge of the periodic input signal. If for example the corresponding edge of the periodic input signal was last detected at the sixth delay element 2, the output signals SEL2, SEL4 and SEL8 output a logic “0” and the output signal SEL6 outputs a logic “1”. The four output drivers are connected to the output ports of the first to fourth delay element of the delay chain, so that only that output driver 8 is turned on by the output signal SEL6 which is connected to the output port of the third delay element 2, the output of which applies the propagating input signal approximately after half of the duration for the phase progress of 180°.

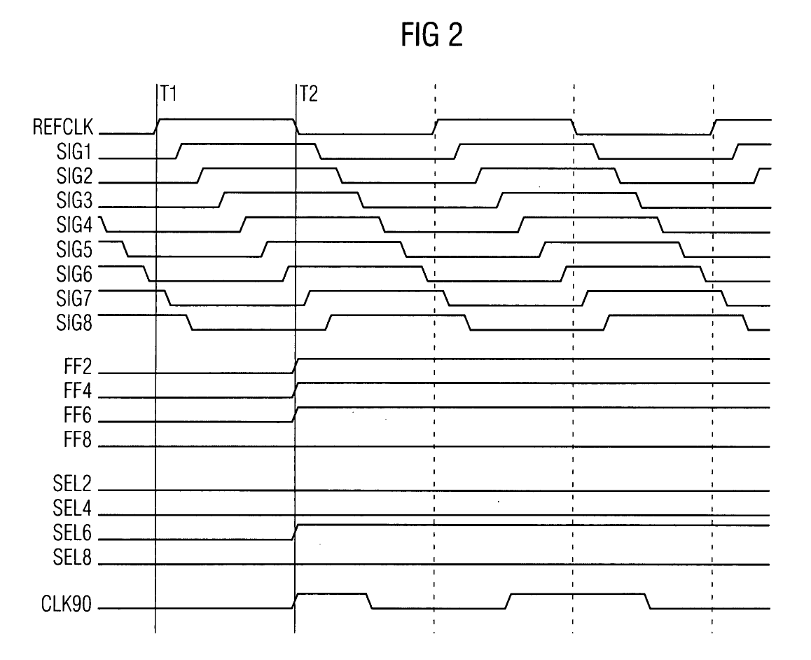

This case is also indicated in the signal-time-diagram shown in FIG. 2. At the point of time T1, a rising edge can be recognized which propagates through the delay chain 1. The output signals at the output ports of the delay elements are shown as signals SIG1 to SIG8. The signals SIG2, SIG4, SIG6 and SIG8 are applied to the data input ports of the first to fourth flip-flop 4. At the point of time T2, a falling edge of the periodic input signal is applied to the input port of the DLL circuit which, inverted by the inverter 5, is applied to the clock input ports of the D-flip-flops 4 as a rising edge. A rising edge at the clock input ports of the D-flip-flops 4 has the effect that the output signal of the delay element 2 applied to each of the data input ports is latched into the respective D-flip-flop 4. Thus, after the time T2, a logic “1” is stored in the first, second and third D-flip-flop and a logic “0” is stored in the fourth D-flip-flop. This means that the rising edge of the input signal at the time T1 has propagated at least until the output port of the sixth delay element 2, but has not yet reached the output port of the eighth delay element 2. By means of the AND gate 6, a control information is now generated which is formed by the selection signals SEL2, SEL4, SEL6 and SEL8. Only the selection signal corresponding to the D-flip-flop or the delay element 2, respectively, which has lastly detected the corresponding edge (rising edge at the time T1 of the periodic input signal)—the subsequent D-flip-flop 4 not having detected this edge—is set to a logic “1”. The selection signal SEL6 now enables an outputting of the output signal of the third delay element (=6:2) so that the periodic input signal is applied to the output port of the DLL circuit with a delay, i.e. a phase shift corresponding to half of the predetermined phase progress, which in the shown example is 180° due to the inverter provided.

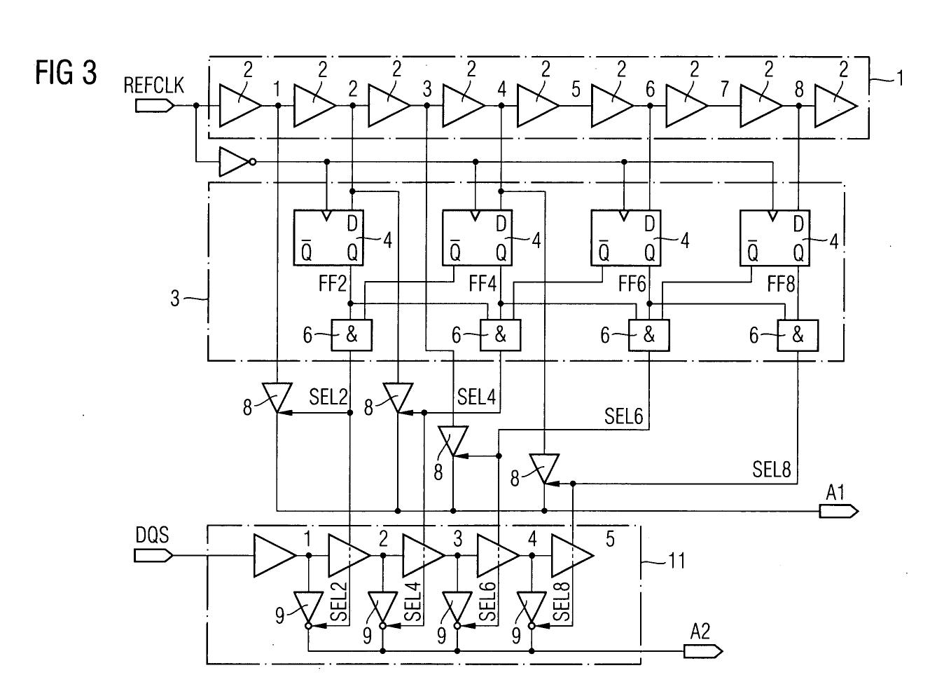

FIG. 3 shows another embodiment of the inventive DLL circuit. The embodiment of FIG. 3 substantially comprises the same DLL circuit illustrated in FIG. 1. Same reference numerals indicate elements having the same or a comparable function. The selection signals SEL2, SEL4, SEL6 and SEL8 generated by the AND gates 6 are forwarded to further selection switches 9 in parallel, the selection switches 9 forwarding the output signal of further delay elements 10 of a further delay chain 11 to a second output port A2 depending on the corresponding output signal SEL2, SEL4, SEL6, SEL8. At the input port of the second delay chain 11, a signal DQS is applied which is to be delayed by the same time as the periodic input signal REFCLK. If the second input signal DQS is a periodic signal with the same periodic duration, such as the first input signal REFCLK, a periodic signal is outputted at the second output port A2, which has the same phase shift as the first output signal at the output A1 of the part corresponding to the DLL circuit of FIG. 1. If the second input signal is not a periodic signal, it is temporarily delayed by a duration which depends on the phase shift of the first input signal and its periodic duration. With a phase shift indicated in degrees, the temporary delay of the second input signal corresponds to the phase shift divided by 360° times the period duration. For example, the first input signal may be a clock signal for the first delay chain, which is to be shifted by a particular phase shift, and the second input signal may be a data signal which is to be subjected to a time delay corresponding to a phase shift in order to be taken over, e.g., into a latch along with the clock signal. Of course, it is also possible to connect the selection switches to the outputs of the further delay elements 10 in a different manner, so that a different relation is achieved between the phase shifts of the first and the second output signals A1, A2. The selection signal SEL6 can, e.g., be applied to a further selection switch 9 connected to the second further delay element 10 in order to achieve a 60°-phase-shifted signal as a second output signal for an identical input signal.

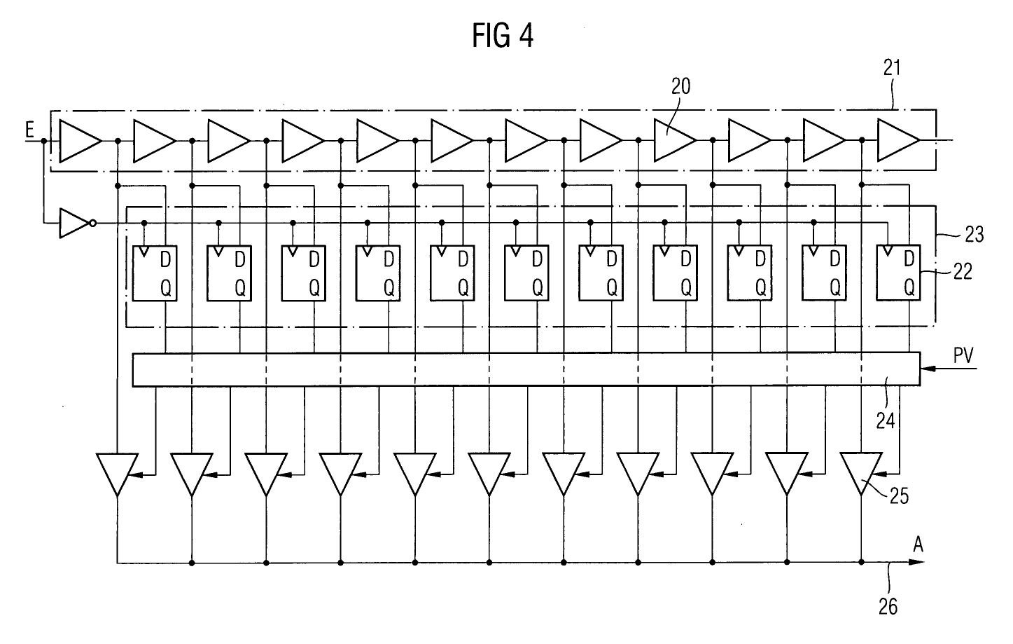

FIG. 4 shows a further embodiment of the inventive DLL circuit. The DLL circuit comprises a plurality of delay elements 20, which are connected in series and form a delay chain 21. At the input port of the delay chain 21, a periodic input signal E is applied which is outputted at the output port as a periodic output signal with a phase shift regarding the input signal E at the input of the DLL circuit, the phase shift being determined by a phase shift signal PV.

In this embodiment, each of the output ports of the delay elements 20 is connected to a data input of the correspondingly associated D-flip-flops 2 of a detection unit 23. As described above, the D-flip-flops 22 comprise a clock input port to which the inverted input signal is applied so that—provided a duty cycle of 50:50 of the input signal—the D-flip-flop is triggered in the case of a phase shift of 180° with regard to the input signal, and the signal applied to the output port of the corresponding delay element 20 is latched into the corresponding D-flip-flop 22. The output ports of the D-flip-flop 22 are connected to a selection circuit 24 which is depicted in FIG. 4 in the form of a block, for ease of illustration. The selection circuit 24 is essentially designed to recognize to which delay element 20 a particular edge of the input signal in the delay chain 21 has propagated after a phase progress of 180°. Thereby, the selection circuit 24 determines how far the input signal has propagated in the delay chain 21 in the case of a phase progress of 180°.

The selection circuit 24 is connected to selection switches 25 via control lines. For each delay element 20, a selection switch 25 is provided. One of the selection switches 25 is turned on in order to apply the output of the delay elements 20 to the output lines 26, so that the signal applied to the corresponding delay element is outputted at the output port.

In a further embodiment, the phase shift signal PV can also instruct the selection circuit 24 so that one of the selection switches 25 connected therewith via a signal connection line is turned on in order to apply the inverted output signal of a selected delay element 20 to the output line 26. In this case, each of the selection switches 25 has at least three predefined switching states depending on a switch control signal supplied by the selection circuit 24 on a basis of the phase shift signal PV, namely one wherein the selection switch 25 is turned off, one wherein the selection switch 25 forwards the signal at its input to its output and one wherein the selection switch receives the signal at its input and outputs the inverted signal. By inverting the signal output by the output of the respective delay element 20, an additional phase shift of 180° can be obtained on the output line 26.

The delays of the delay elements 20 are essentially identical. If, for example, a certain edge of the periodic input signal has reached the tenth delay element, but not the eleventh delay element, this means that the total delay of the ten delay elements approximately corresponds to a phase progress of 180°, i.e., each one of the delay elements causes a phase delay of 18°.

The selection circuit 24 receives a phase delay value PV as input signal, which indicates by which phase shift the periodic input signal is to be shifted. If a phase shift of 90° is desired, the selection circuit 24 determines that the output of the fifth delay element 20 is applied to the output line 26. The fifth delay element results from the fact that the five-fold phase shift of 18° (5×18°=90°) with regard to the input signal is to be outputted as output signal A. If a phase delay of, e.g., 270° is to be outputted, this corresponds to the output of the fifteenth delay element 20, etc. The selection circuit 24 is designed such that only one of the output ports of each delay element 20 is applied to the output line A in order to avoid conflicting driving of the various logic levels. Generally, the number of the delay element the output of which is turned on to the output line 26 can be calculated from the following formula:
Number of the delay element=desired phase shift/particular phase progress (180°)/Number of the delay element lastly reached by the certain edge

The embodiment of FIG. 4 allows for setting the phase shift of an output signal at the output port A with regard to the periodic input signal E as desired and depending on the predetermined phase shift value.

The features of the various embodiments of the disclosed DLL circuit may be exchanged or supplemented as desired, provided they are not technically incompatible, without departing from the scope of the invention.

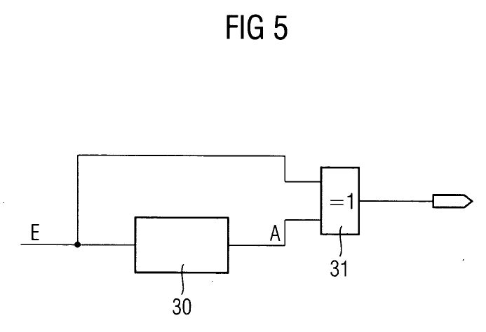

FIG. 5 shows a clock frequency doubling circuit according to a further aspect of the present invention. The clock frequency doubling unit comprises a DLL circuit 30 effecting a 90° phase shift, as depicted, e.g., in FIG. 1. The output port of the DLL circuit 30 is connected to a first input port of the exclusive OR-gate 31, at the second input port of which the periodic input signal is applied. At the output port of the exclusive OR-gate 31, a periodic output signal may be tapped which comprises twice the frequency of the periodic input signal. Preferably, the periodic input signal should comprise a duty cycle of 50:50, so that a duty cycle of 50:50 can also be achieved for an output signal with twice the frequency.

The DLL circuit or the clock frequency doubling circuit built from the DLL circuit, respectively, provide the advantage that they may be configured in the same manner as conventional circuits with only little circuitry and particularly with lower demands on the electronic components used therein.

While the foregoing is directed to embodiments of the present invention, other and further embodiments of the invention may be devised without departing from the basic scope thereof, and the scope thereof is determined by the claims that follow.

What is claimed is:

1. A delay locked loop (DLL) circuit for providing an output signal which is phase-shifted with a desired phase shift with respect to a periodic input signal, the DLL circuit comprising:
a plurality of delay elements, each having substantially same the delay time, connected in series to form a delay chain, wherein the periodic input signal is applied to the first delay element of the delay chain;
a detection unit connected to outputs of at least a portion of the plurality of delay elements, the detection unit configured to determine which delay element a particular edge of the periodic input signal has reached after a predetermined phase progress of the periodic input signal and to generate a control signal which indicates at which delay element the particular edge of the periodic input signal has last been detected; and
a selection circuit configured to select one of the delay elements depending on the control signal and depending on the desired phase shift and to output a respective signal at a respective output of the selected delay element as the output signal of the DLL circuit.

2. The DLL circuit of claim 1, further comprising:
a second delay chain comprising a second plurality of delay elements, the second delay chain having substantially same design as the delay chain; and
a second selection unit configured to select one of the delay elements in the second delay chain depending on the control signal and depending on a desired further phase shift and to output a respective signal at a respective output of the selected delay element of the second delay chain as a further output signal.

3. The DLL circuit of claim 2, wherein a further periodic input signal is applied to a first delay element of the second delay chain.

4. The DLL circuit of claim 1, wherein the detection unit comprises a plurality of D-flip-flop circuits, each connected to a respective output of a respective delay element of the delay chain, wherein the periodic input signal combined with the predetermined phase shift is applied to a clock input of each D-flip-flop circuit to latch a respective signal at the respective output of the respective delay element into the respective D-flip-flop circuit in accordance with an edge of the input signal delayed by the predetermined phase progress, and further comprising:
an evaluation unit configured to generate the control signal depending on the respective latched values of the D-flip-flop circuits.

5. The DLL circuit of claim 4, wherein the detection unit is configured to apply the periodic input signal to the clock inputs of the D-flip-flop circuits in order to determine a phase progress of 360°.

6. The DLL circuit of claim 4, wherein the detection unit is configured to apply an inverted periodic input signal to the clock inputs of the D-flip-flop circuits in order to determine a phase progress of 180°.

7. The DLL circuit of claim 4, wherein the periodic input signal charged with the predetermined phase progress is applied to the clock inputs of the D-flip-flop circuits substantially simultaneously.

8. The DLL circuit of claim 1, wherein the selection circuit selects the delay element from the plurality of delay elements at a predetermined position and outputs the respective signal at the respective output of the selected delay element as the output signal.

9. The DLL circuit of claim 8, wherein the predetermined position of the delay element is determined by the desired phase shift divided by a single phase shift of the delay element, the single phase shift being determined by the control signal and the predetermined phase progress.

10. The DLL circuit of claim, wherein the evaluation unit comprises a plurality of AND gates corresponding the plurality of D-flip-flop circuits, and wherein each AND gate is connected to a non-inverted output of a respective D-flip-flop circuit and at least one of a non-inverted output of a previous D-flip-flop circuit and an inverted output of a next D-flip-flop circuit.

11. The DLL circuit of claim 10, wherein the selection circuit comprises switchable output drivers which are selectively activated by the control signal.

12. A delay locked loop (DLL) circuit for providing an output signal which is phase-shifted with a desired phase shift with respect to a periodic input signal, the DLL circuit comprising:
a plurality of delay elements, each having same delay time, connected in series to form a delay chain, wherein the periodic input signal is applied to a first delay element of the delay chain;
a detection unit connected to respective outputs of at least one portion of the delay elements, the detection unit configured to determine which delay element a particular edge of the periodic input signal has reached after a predetermined phase progress of the periodic input signal and to generate a control signal which indicates at which delay element the particular edge of the periodic input signal has last been detected; and
a selection circuit configured to select one of the delay elements depending on the control signal and depending on the desired phase shift and to output, as the output signal of the DLL circuit, one of an inverted signal and a non-inverted signal at the respective output of the respective delay element which is selected.

13. The DLL circuit of claim 12, further comprising,
a second delay chain comprising a second plurality of delay elements, the second delay chain having substantially same design as the delay chain; and
a second selection unit configured to select one of the delay elements in the second delay chain depending on the control signal and depending on a desired further phase shift and to output a respective signal at a respective output of the selected delay element of the second delay chain as a further output signal.

14. The DLL circuit of claim 13, wherein a further periodic input signal is applied to a first delay element of the second delay chain.

15. The DLL circuit of claim 14, wherein the further periodic input signal comprises a data signal having a different frequency than the periodic input signal.

16. A clock duplication circuit, comprising:
a delay locked loop (DLL) circuit for providing a phase-shifted output signal with a desired phase shift of 90° with respect to a periodic input signal, the DLL circuit comprising:
a plurality of delay elements, each having substantially same delay time, connected in series to form a delay chain, wherein the periodic input signal is applied to the first delay element of the delay chain;
a detection unit connected to outputs of at least a portion of the plurality of delay elements, the detection unit configured to determine which delay element a particular edge of the periodic input signal has reached after a predetermined phase progress of the periodic input signal and to generate a control signal which indicates at which delay element the particular edge of the periodic input signal has last been detected; and
a selection circuit configured to select one of the delay elements depending on the control signal and to output a respective signal at a respective output of the selected delay element as the phase-shifted output signal of the DLL circuit; and
an exclusive-OR gate connected to receive the periodic input signal and the phase-shifted output signal and to provide an output signal with duplicated clock frequency at an output of the exclusive-or-gate.

17. The clock duplication circuit of claim 16, wherein the detection unit comprises a plurality of D-flip-flop circuits, each connected to a respective output of a respective delay element of the delay chain, wherein the periodic input signal combined with the predetermined phase shift is applied to a clock input of each D-flip-flop circuit to latch a respective signal at the respective output of the respective delay element into the respective D-flip-flop circuit in accordance with an edge of the input signal delayed by the predetermined phase progress.

18. The clock duplication circuit of claim 17, wherein the DLL circuit further comprises an evaluation unit configured to generate the control signal depending on the respective latched values of the D-flip-flop circuits.

19. The clock duplication circuit of claim 18, wherein the evaluation unit comprises a plurality of AND gates corresponding the plurality of D-flip-flop circuits, and wherein each AND gate is connected to a non-inverted output of a respective D-flip-flop circuit and at least one of a non-inverted output of a previous D-flip-flop circuit and an inverted output of a next D-flip-flop circuit.

20. The clock duplication circuit of claim 19, wherein the selection circuit comprises switchable output drivers which are selectively activated by the control signal.
